(19) United States
(12) Patent Application Publication
(10) Pub. No.: US 2025/0168978 A1
(43) Pub. Date: May 22, 2025

(54) ELECTRONIC COMPONENT

(71) Applicant: Murata Manufacturing Co., Ltd., Nagaokakyo-shi (JP)

(72) Inventors: Yosuke MATSUSHITA, Nagaokakyo-shi (JP); Mitsutoshi IMAMURA, Nagaokakyo-shi (JP)

(21) Appl. No.: 19/032,102

(22) Filed: Jan. 19, 2025

Related U.S. Application Data
(63) Continuation of application No. PCT/JP2023/022374, filed on Jun. 16, 2023.

(30) Foreign Application Priority Data
Jul. 20, 2022 (JP) 2022-115537

(51) Int. Cl. H05K 1/11

(52) U.S. Cl. CPC H05K 1/11; H05K 2201/09036

(57) ABSTRACT

An electronic component includes a board body of a plate shape having an upper principal surface and a lower principal surface, and one or more external electrodes provided on the lower principal surface of the board body. A surface located in a center in an up-down direction of the board body is defined as a central surface. The central surface, when viewed in a front-back direction, is curved so that the center of the central surface may be located above or below a left end of the central surface and a right end of the central surface. The lower principal surface, when viewed in the front-back direction, has one or more first inclined regions in which the lower principal surface is inclined with respect to a left-right direction, and one or more first adjacent regions adjacent to the one or more first inclined regions.

### CROSS REFERENCE TO RELATED APPLICATION

This is a continuation of International Application No. PCT/JP2023/022374 filed on Jun. 16, 2023 which claims priority from Japanese Patent Application No. 2022-115537 filed on Jul. 20, 2022. The contents of these applications are incorporated herein by reference in their entireties.

### BACKGROUND OF THE DISCLOSURE

### Field of the Disclosure

The present disclosure relates to an electronic component including an external electrode.

### Description of the Related Art

As an invention related to the conventional electronic component, for example, a laminate filter disclosed in Patent Literature 1 is known. This laminate filter includes a laminate and a plurality of electrodes. The laminate has a plate shape having an upper principal surface and a lower principal surface. The plurality of electrodes are provided on the lower principal surface. The laminate filter described above is mounted on a circuit board. Specifically, the circuit board includes a plurality of electrodes. Then, a plurality of electrodes of the electronic component are fixed to the plurality of electrodes of the circuit board with solder.
(Patent Literature 1) International Publication No. 2017/199734

### BRIEF SUMMARY OF THE DISCLOSURE

Incidentally, in the laminate filter disclosed in Patent Literature 1, warping may occur in the laminate. When warping occurs in the laminate, variation occurs in positions in an up-down direction of the plurality of electrodes. In such a case, a mounting failure may occur in mounting the laminate filter to the circuit board.

In view of the foregoing, exemplary embodiments of the present disclosure are directed to provide an electronic component capable of significantly reducing occurrence of a mounting failure.

An electronic component according to one exemplary embodiment of the present disclosure includes a board body of a plate shape having an upper principal surface and a lower principal surface, and one or more external electrodes provided on the lower principal surface of the board body, and a surface located in a center in an up-down direction of the board body is defined as a central surface, the central surface, when viewed in a front-back direction, is curved so that the center of the central surface may be located above or below a left end of the central surface and a right end of the central surface, the lower principal surface, when viewed in the front-back direction, has one or more first inclined regions in which the lower principal surface is inclined with respect to a left-right direction, and one or more first adjacent regions adjacent to the one or more first inclined regions, and each of the one or more first adjacent regions has a larger area than 0 and none of the one or more first adjacent regions is located below a lower end of the one or more first inclined regions.

According to the electronic component in the present disclosure, the occurrence of a mounting failure is able to be significantly reduced.

### BRIEF DESCRIPTION OF THE SEVERAL VIEWS OF THE DRAWINGS

FIG. 1 is a perspective view of an electronic component 10.

FIG. 2 is a cross-sectional view of the electronic component 10.

FIG. 3 is a cross-sectional view of an electronic component 10a.

FIG. 4 is a cross-sectional view of an electronic component 10b.

FIG. 5 is a perspective view of an electronic component 10c.

FIG. 6 is a cross-sectional view of the electronic component 10c.

FIG. 7 is a perspective view of an electronic component 10d.

### DETAILED DESCRIPTION OF THE DISCLOSURE

### Exemplary Embodiment

### (Structure of Electronic Component)

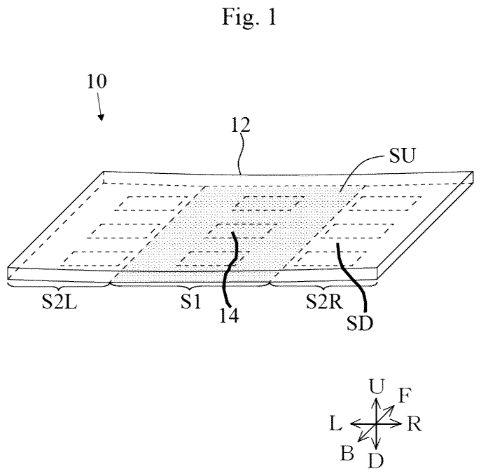

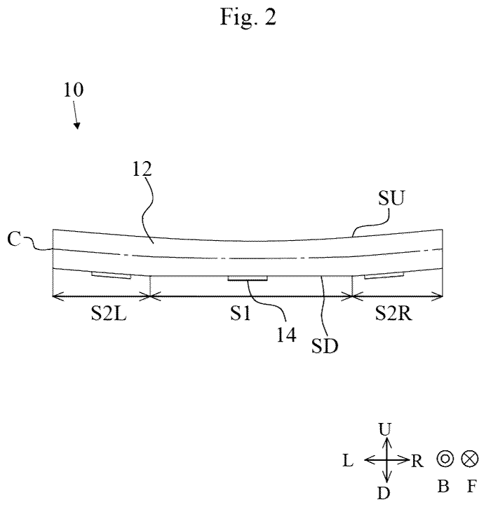

Hereinafter, a structure of an electronic component 10 according to exemplary embodiments of the present disclosure will be described with reference to drawings. FIG. 1 is a perspective view of the electronic component 10. FIG. 2 is a cross-sectional view of the electronic component 10. It is to be noted that, in the drawings, a reference sign is assigned only to a representative external electrode 14 of nine external electrodes 14.

In the present specification, directions are defined as follows. A direction in which an upper principal surface SU and a lower principal surface SD of a board body 12 of the electronic component 10 are arranged side by side is defined as an up-down direction. When viewed in the up-down direction, a direction in which a long side of the board body 12 extends is defined as a left-right direction. When viewed in the up-down direction, a direction in which a short side of the board body 12 extends is defined as a front-back direction. The up-down direction, the left-right direction, and the front-back direction are orthogonal to each other. It is to be noted that the up-down direction, the front-back direction, and the left-right direction in the present exemplary embodiment may not match the up-down direction, the front-back direction, and the left-right direction during the use of the electronic component 10.

The electronic component 10 is a laminated electronic component to be mounted on a non-illustrated circuit board. The electronic component 10, as shown in FIG. 1, includes a board body 12 and nine external electrodes 14.

The board body 12, as shown in FIG. 1, has a plate shape. The board body 12 has an upper principal surface SU and a lower principal surface SD. The upper principal surface SU and the lower principal surface SD, when viewed in the up-down direction, have a rectangular shape. The board body 12 has a structure in which a plurality of insulator layers are stacked in the up-down direction. The plurality of insulator layers are sintered ceramic layers, for example. In addition, a circuit element configured by a conductor layer and an interlayer connection conductor is provided inside the board body 12. The circuit element may be an inductor, a capacitor, or an LC filter, for example.

The nine external electrodes 14 are provided on the lower principal surface SD of the board body 12. The nine external electrodes 14 are arranged in a matrix of three rows by three columns. Each of the nine external electrodes 14, when viewed in the up-down direction, has a rectangular shape.

Incidentally, as shown in FIG. 2, a surface located in the center in the up-down direction of the board body 12 is defined as a central surface C. The board body 12 is curved so as to protrude in the down direction. Therefore, the central surface C, when viewed in the front-back direction, is curved so that the center of the central surface C may be located below a left end of the central surface C and a right end of the central surface C. Then, the lower principal surface SD, when viewed in the front-back direction, has first inclined regions S2L and S2R in which the lower principal surface SD is inclined with respect to the left-right direction, and a first adjacent region S1 adjacent to the first inclined regions S2L and S2R. In the present exemplary embodiment, the number of first adjacent regions S1 is one. The number of first inclined regions S2L and S2R is two. In the left-right direction, the first adjacent region S1 is located between the first inclined region S2L and the first inclined region S2R. Accordingly, the first inclined region S2L is located in the left of the first adjacent region S1. Then, a left end of the first inclined region S2L is located above a right end of the first inclined region S2L. The first inclined region S2R is located in the right of the first adjacent region S1. A right end of the first inclined region S2R is located above a left end of the first inclined region S2R.

The first adjacent region S1 has a larger area than 0 and is not located below a lower end of the first inclined region S2L or S2R. More specifically, the first adjacent region S1 is not a line or a point of which the area is 0. In the present exemplary embodiment, the first adjacent region S1 has a rectangular shape. Then, the first adjacent region S1 is in contact with a front side and a back side of the lower principal surface SD.

In addition, the first adjacent region S1 includes a plane. A left end of the first adjacent region S1 matches the right end of the first inclined region S2R. A right end of the first adjacent region S1 matches the left end of the first inclined region S2L. Accordingly, a position in the up-down direction of the plane of the first adjacent region S1 matches a position in the up-down direction of the lower end of the first inclined regions S2L and S2R.

The electronic component 10 described above is mounted on a circuit board. Specifically, nine external electrodes are provided on an upper principal surface of the circuit board. The nine external electrodes 14 each are fixed to the nine external electrodes of the circuit board with solder.

### (Effects)

According to the electronic component 10, the occurrence of a mounting failure is able to be significantly reduced. More specifically, in the electronic component 10, the central surface C, when viewed in the front-back direction, is curved so that the center of the central surface C may be located below the left end of the central surface C and the right end of the central surface C. In other words, warping occurs in the electronic component 10. The lower principal surface SD, when viewed in the front-back direction, has the first inclined regions S2L and S2R in which the lower principal surface SD is inclined with respect to the left-right direction, and the first adjacent region S1 adjacent to the first inclined regions S2L and S2R. Then, the first adjacent region S1 has a larger area than 0 and is not located below the lower end of the first inclined region S2L or S2R. Accordingly, a position in the up-down direction of the external electrode 14 provided in the first adjacent region S1 is closer to a position in the up-down direction of the external electrode 14 provided in in the first inclined region S2L and a position in the up-down direction of the external electrode 14 provided in the first inclined region S2R. As a result, all the nine external electrodes 14 are brought close to the nine external electrodes of the circuit board. Therefore, according to the electronic component 10, the occurrence of a mounting failure is able to be significantly reduced.

### First Modification

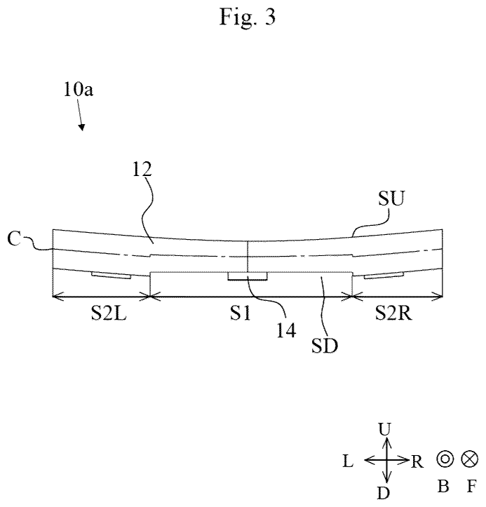

Hereinafter, an electronic component 10a according to a first modification of the present disclosure will be described with reference to drawings. FIG. 3 is a cross-sectional view of the electronic component 10a.

The electronic component 10a is different from the electronic component 10 in the shape of the first adjacent region S1. More specifically, the first adjacent region S1 includes a depression. Accordingly, the position in the up-down direction of the plane of the first adjacent region S1 is located above the position in the up-down direction of the lower end of the first inclined regions S2L and S2R. Since the remaining structure of the electronic component 10a is the same as the structure of the electronic component 10, the description will be omitted. The electronic component 10a is able to obtain the same advantageous effects as the electronic component 10.

### Second Modification

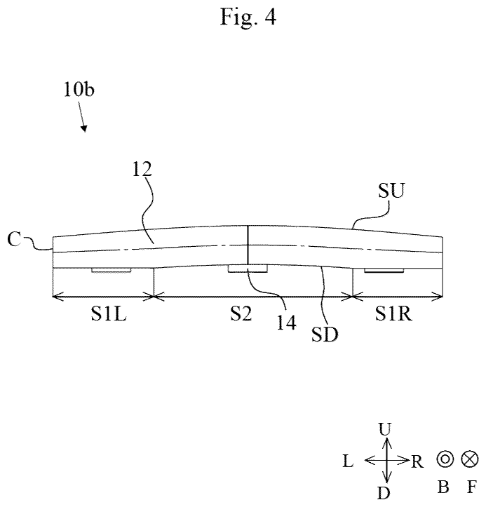

Hereinafter, an electronic component 10b according to a second modification of the present disclosure will be described with reference to drawings. FIG. 4 is a cross-sectional view of the electronic component 10b.

The electronic component 10b is different from the electronic component 10 in the direction in which the central surface C is curved. More specifically, the central surface C, when viewed in the front-back direction, is curved so that the center of the central surface C may be located above the left end of the central surface C and the right end of the central surface C. The lower principal surface SD, when viewed in the front-back direction, has a first inclined region S2 in which the lower principal surface SD is inclined with respect to the left-right direction, and first adjacent regions S1L and S1R adjacent to the first inclined region S2. In the present exemplary embodiment, the number of first adjacent regions S1L and S1R is two. In the left-right direction, the first inclined region S2 is located between the first adjacent regions S1L and S1R. The first adjacent region S1L is located in the left of the first inclined region S2. The first adjacent region SIR is located in the right of the first inclined region S2.

The first adjacent regions S1L and SIR have a larger area than 0 and the first adjacent region S1L or SIR is not located below a lower end of the first inclined region S2. More specifically, the first adjacent region S1L or S1R is not a line or a point of which the area is 0. In the present exemplary embodiment, the first adjacent regions S1L and SIR have a rectangular shape. Then, the first adjacent region S1L is in contact with a front side, a back side, and a left side of the lower principal surface SD. The first adjacent region SIR is in contact with a front side, a back side, and a right side of the lower principal surface SD.

In addition, the first adjacent regions S1L and S1R include a plane. A right end of the first adjacent region S1L matches a left end of the first inclined region S2. A left end of the first adjacent region SIR matches a right end of the first inclined region S2. Accordingly, a position in the up-down direction of the plane of the first adjacent regions S1L and S1R matches a position in the up-down direction of the lower end of the first inclined region S2. Since the remaining structure of the electronic component 10b is the same as the structure of the electronic component 10, the description will be omitted. The electronic component 10b is able to obtain the same advantageous effects as the electronic component 10.

### Third Modification

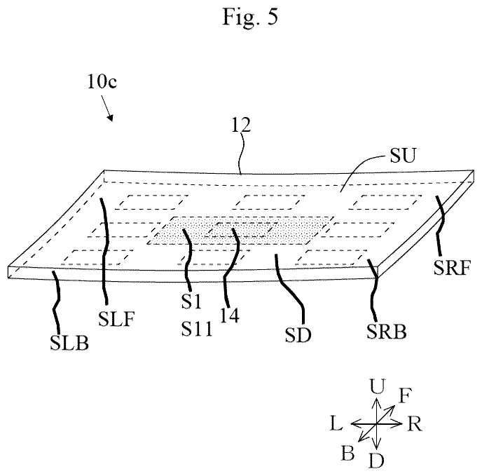

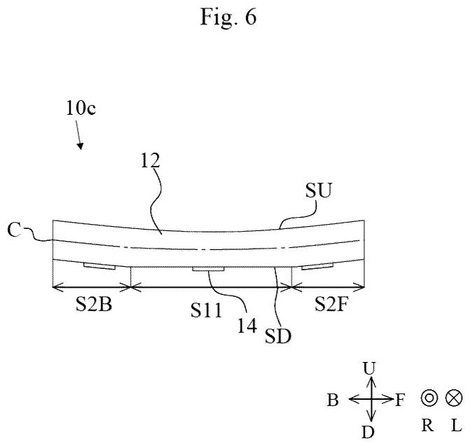

Hereinafter, an electronic component 10c according to a third modification of the present disclosure will be described with reference to drawings. FIG. 5 is a perspective view of the electronic component 10c. FIG. 6 is a cross-sectional view of the electronic component 10c. It is to be noted that, in the drawings, a reference sign is assigned only to a representative external electrode 14 of the nine external electrodes 14.

The electronic component 10c is different from the electronic component 10 in that the central surface C, when viewed in the front-back direction, is curved so that the center of the central surface C may be located below the left end of the central surface C and the right end of the central surface C, and the central surface C, when viewed in the left-right direction, is curved so that the center of the central surface C may be located below a front end of the central surface C and a back end of the central surface C. It is to be noted that, since the structure in the electronic component 10c in which the central surface C, when viewed in the front-back direction, is curved so that the center of the central surface C may be located below the left end of the central surface C and the right end of the central surface C is the same as the structure of the electronic component 10, the description will be omitted.

The lower principal surface SD, when viewed in the left-right direction, has second inclined regions S2F and S2B in which the lower principal surface SD is inclined with respect to the front-back direction, and a second adjacent region S11 adjacent to the second inclined regions S2F and S2B. In the present exemplary embodiment, the number of second adjacent regions S11 is one. The number of second inclined regions S2F and S2B is two. In the front-back direction, the second adjacent region S11 is located between the second inclined region S2F and the second inclined region S2B. Then, the second adjacent region S11 is not located below a lower end of the second inclined region S2F or S2B.

As described above, in the electronic component 10c, the central surface C, when viewed in the front-back direction, is curved so that the center of the central surface C may be located below the left end of the central surface C and the right end of the central surface C, and the central surface C, when viewed in the left-right direction, is curved so that the center of the central surface C may be located below the front end of the central surface C and the back end of the central surface C. Therefore, the first adjacent region S1 or the second adjacent region S11 is not located below a lower end of a region SRF located at a right front of the first adjacent region S1 and the second adjacent region S11, a lower end of a region SLF located at a left front of the first adjacent region S1 and the second adjacent region S11, a lower end of a region SRB located at a right back of the first adjacent region S1 and the second adjacent region S11, or a lower end of a region SLB located at a left back of the first adjacent region S1 and the second adjacent region S11. It is to be noted that the present exemplary embodiment, for convenience of description, describes the first adjacent region S1 and the second adjacent region S11, by different reference signs. However, the first adjacent region S1 and the second adjacent region S11 are the same regions. Since the remaining structure of the electronic component 10c is the same as the structure of the electronic component 10, the description will be omitted. The electronic component 10c is able to obtain the same advantageous effects as the electronic component 10.

### Fourth Modification

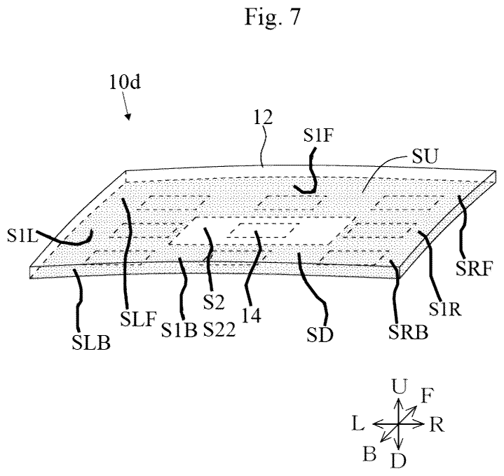

Hereinafter, a structure of an electronic component 10d according to a fourth modification of the present disclosure will be described with reference to drawings. FIG. 7 is a perspective view of the electronic component 10d. It is to be noted that, in the drawings, a reference sign is assigned only to a representative external electrode 14 of the nine external electrodes 14.

The electronic component 10d is different from the electronic component 10b in that the central surface C, when viewed in the front-back direction, is curved so that the center of the central surface C may be located above the left end of the central surface C and the right end of the central surface C, and the central surface C, when viewed in the left-right direction, is curved so that the center of the central surface C may be located above the front end of the central surface C and the back end of the central surface C. It is to be noted that, since the structure in the electronic component 10d n which the central surface C, when viewed in the front-back direction, is curved so that the center of the central surface C may be located above the left end of the central surface C and the right end of the central surface C is the same as the structure of the electronic component 10b, the description will be omitted.

The lower principal surface SD, when viewed in the left-right direction, has a second inclined region S22 in which the lower principal surface SD is inclined with respect to the front-back direction, and second adjacent regions S1F and S1B adjacent to the second inclined region S22. In the present exemplary embodiment, the number of second adjacent regions SIF and S1B is two. The number of second inclined regions S22 is one. In the front-back direction, the second inclined region S22 is located between the second adjacent region SIF and the second adjacent region S1B. Then, the second adjacent region S1F or S1B is not located below a lower end of the second inclined region S22.

As described above, in the electronic component 10d, the central surface C, when viewed in the front-back direction, is curved so that the center of the central surface C may be located above the left end of the central surface C and the right end of the central surface C, and the central surface C, when viewed in the left-right direction, is curved so that the center of the central surface C may be located above the front end of the central surface C and the back end of the central surface C. Therefore, the region SRF located at a right front of the first inclined region S2 and the second inclined region S22, the region SLF located at a left front of the first inclined region S2 and the second inclined region S22, the region SRB located at a right back of the first inclined region S2 and the second inclined region S22, or the region SLB located at a left back of the first inclined region S2 and the second inclined region S22 is not located below the lower end of the first inclined region S2 or the second inclined region S22. It is to be noted that the present exemplary embodiment, for convenience of description, describes the first inclined region S2 and the second inclined region S22, by different reference signs. However, the first inclined region S2 and the second inclined region S22 are the same regions. Since the remaining structure of the electronic component 10d is the same as the structure of the electronic component 10b, the description will be omitted. The electronic component 10d is able to obtain the same advantageous effects as the electronic component 10b.

### Other Exemplary Embodiments

Electronic components according to the present disclosure are not limited to the electronic components 10 and 10a to 10d and various changes and modifications may be possible within the scope of the present disclosure. It is to be noted that the structures of the electronic components 10 and 10a to 10d may be optionally combined.

It is to be noted that, in the electronic component 10c, the central surface C, when viewed in the front-back direction, may be curved so that the center of the central surface C may be located above the left end of the central surface C and the right end of the central surface C, and the central surface C, when viewed in the left-right direction, may be curved so that the center of the central surface C may be located above and below the front end of the central surface C and the back end of the central surface C.

It is to be noted that the electronic components 10 and 10a to 10d may include one or more external electrodes 14.
10, 10a to 10d: electronic component
12: board body
14: external electrode
C: central surface
S1, S1L, S1R: first adjacent region
S1F, S1B: second adjacent region
S2, S2L, S2R: first inclined region
S2F, S2B: second inclined region
SD: lower principal surface
SU: upper principal surface

1. An electronic component comprising:
a board body of a plate shape having an upper principal surface and a lower principal surface and being curved; and
one or more external electrodes provided on the lower principal surface of the board body, wherein:
a surface located in a center in an up-down direction of the board body is defined as a central surface;
the central surface, when viewed in a front-back direction, is curved throughout the central surface from a left end of the central surface to a right end of the central surface so that the center of the central surface is located above or below the left end of the central surface and the right end of the central surface;
the lower principal surface, when viewed in the front-back direction, has one or more first inclined regions in which the lower principal surface is inclined with respect to a left-right direction, and one or more first adjacent regions adjacent to the one or more first inclined regions; and
each of the one or more first adjacent regions has a larger area than 0, and none of the one or more first adjacent regions is located below a lower end of the one or more first inclined regions.

2. The electronic component according to claim 1, wherein:
the central surface, when viewed in the front-back direction, is curved so that the center of the central surface is located below the left end of the central surface and the right end of the central surface;
the one or more first adjacent regions include one first adjacent region;
the one or more first inclined regions include two first inclined regions; and
in the left-right direction, the one first adjacent region is located between the two first inclined regions.

3. The electronic component according to claim 1, wherein:
the central surface, when viewed in the front-back direction, is curved so that the center of the central surface is located above the left end of the central surface and the right end of the central surface;
the one or more first adjacent regions include two first adjacent regions;
the one or more first inclined regions include one first inclined region; and
in the left-right direction, the one first inclined region is located between the two first adjacent regions.

4. The electronic component according to claim 1, wherein the one or more first adjacent regions include a depression.

5. The electronic component according to claim 1, wherein:
the one or more first adjacent regions include a plane; and
a position of the plane in the up-down direction matches a position of the lower end of the one or more first inclined regions in the up-down direction.

6. The electronic component according to claim 1, wherein:
the central surface, when viewed in the left-right direction, is curved so that the center of the central surface is located above or below a front end of the central surface and a back end of the central surface;
the lower principal surface, when viewed in the left-right direction, has one or more second inclined regions in which the lower principal surface is inclined with respect to the front-back direction, and one or more second adjacent regions adjacent to the one or more second inclined regions; and
none of the one or more second adjacent regions is located below a lower end of the one or more second inclined regions.

7. The electronic component according to claim 6, wherein:
the central surface, when viewed in the front-back direction, is curved so that the center of the central surface is located below the left end of the central surface and the right end of the central surface, and, when viewed in the left-right direction, is curved so that the center of the central surface is located below the front end of the central surface and the back end of the central surface;
the one or more first adjacent regions include one first adjacent region;
the one or more first inclined regions include two first inclined regions;
the one or more second adjacent regions include one second adjacent region;
the one or more second inclined regions include two second inclined regions;
in the left-right direction, the one first adjacent region is located between the two first inclined regions; and
in the front-back direction, the one second adjacent region is located between the two second inclined regions.

8. The electronic component according to claim 7, wherein the first adjacent region or the second adjacent region is not located below a lower end of a region located at a right front of the first adjacent region, a lower end of a region located at a left front of the first adjacent region, a lower end of a region located at a right back of the first adjacent region, or a lower end of a region located at a left back of the first adjacent region.

9. The electronic component according to claim 6, wherein:
the central surface, when viewed in the front-back direction, is curved so that the center of the central surface is located above the left end of the central surface and the right end of the central surface, and, when viewed in the left-right direction, is curved so that the center of the central surface is located above the front end of the central surface and the back end of the central surface;
the one or more first adjacent regions include two first adjacent regions;
the one or more first inclined regions include one first inclined region;
the one or more second adjacent regions include two second adjacent regions;
the one or more second inclined regions include one second inclined region;
in the left-right direction, the one first inclined region is located between the two first adjacent regions; and
in the front-back direction, the one second inclined region is located between the two second adjacent regions.

10. The electronic component according to claim 9, wherein a region located at a right front of the first inclined region and the second inclined region, a region located at a left front of the first inclined region and the second inclined region, a region located at a right back of the first inclined region and the second inclined region, or a region located at a left back of the first inclined region and the second inclined region is not located below a lower end of the first inclined region or the second inclined region.

11. The electronic component according to claim 2, wherein the one or more first adjacent regions include a depression.

12. The electronic component according to claim 3, wherein the one or more first adjacent regions include a depression.

13. The electronic component according to claim 2, wherein:
the one or more first adjacent regions include a plane; and
a position of the plane in the up-down direction matches a position of the lower end of the one or more first inclined regions in the up-down direction.

14. The electronic component according to claim 3, wherein:
the one or more first adjacent regions include a plane; and
a position of the plane in the up-down direction matches a position of the lower end of the one or more first inclined regions in the up-down direction.
